(19) United States
(12) Patent Application Publication
(10) Pub. No.: US 2025/0176286 A1
(43) Pub. Date: May 29, 2025

(54) IMAGE SENSING DEVICE AND METHOD FOR MANUFACTURING THE SAME

(71) Applicant: SK hynix Inc., Icheon-si (KR)

(72) Inventors: Hyo Jun KWON, Icheon-si (KR); Hyun Soo LIM, Icheon-si (KR)

(21) Appl. No.: 18/632,076

(22) Filed: Apr. 10, 2024

(30) Foreign Application Priority Data
Nov. 23, 2023 (KR) 10-2023-0164617

(51) Int. Cl. H01L 27/146; H04N 25/77

(52) U.S. Cl. CPC H10F 39/80373; H04N 25/77; H10F 39/016

(57) ABSTRACT

Image sensing devices are disclosed. In an embodiment, an image sensing device may include: a substrate; a photodiode formed in the substrate; a transfer transistor formed on the substrate; and an oxide transistor formed over the transfer transistor, and the oxide transistor may include: a gate electrode formed over the transfer transistor; a gate isolation layer formed on the gate electrode; an oxide layer formed on the gate isolation layer; a first electrode formed on one side of the oxide layer; and a second electrode formed on another side of the oxide layer.

### PRIORITY CLAIM AND CROSS REFERENCE TO RELATED APPLICATION

This patent document claims the priority and benefits of Korean Patent Application No. 10-2023-0164617, filed on Nov. 23, 2023, which is incorporated by reference in its entirety as part of the disclosure of this patent document.

### TECHNICAL FIELD

Various embodiments of the disclosed technology relate to an image sensing device and a method for manufacturing the same.

### BACKGROUND

An image sensing device refers to a semiconductor device that captures optical images and converts them to electrical signals. With the development of automobile, medical, computer and telecommunication industries, the demand for high-performance image sensing devices is increasing in various devices such as smart phones, digital cameras, game devices, Internet of Things, robots, security cameras, and medical micro-cameras.

The most common types of image sensing devices are charge coupled device (CCD) image sensing devices and complementary metal oxide semiconductor (CMOS) image sensing devices.

### SUMMARY

The disclosed technology can be implemented in some embodiments to provide an image sensing device that can exhibit a high thermal process margin while minimizing the degradation.

In an embodiment, an image sensing device may include: a substrate; a photodiode formed in the substrate; a transfer transistor formed on the substrate; and an oxide transistor formed over the transfer transistor, and the oxide transistor may include: a gate electrode formed over the transfer transistor; a gate isolation layer formed on the gate electrode; an oxide layer formed on the gate isolation layer; a first electrode formed on one side of the oxide layer; and a second electrode formed on another side of the oxide layer. In one example, the transfer transistor is configured to transfer electrical charges generated by the photodiode. In one example, the oxide transistor is configured to reset the photodiode.

The image sensing device may further include: a floating diffusion region formed over the photodiode and below the transfer transistor.

The image sensing device may further include: an electrically conductive path structured to electrically connect the oxide transistor and the floating diffusion region to each other.

The gate electrode may include doped polysilicon.

The gate isolation layer may include a silicon oxide.

The oxide layer may include an oxide-based thin film transistor (TFT) material.

In another embodiment, method for manufacturing an image sensing device may include: forming a photodiode in a substrate; forming a transfer transistor over the substrate; forming a photoresist layer over the transfer transistor; forming a channel region for forming a stacked transistor in one region of the photoresist layer; and forming an oxide transistor in the channel region of the photoresist layer, and the forming the oxide transistor may include stacking a gate electrode, a gate isolation layer, and an oxide layer in the channel region of the photoresist layer. In one example, the transfer transistor is configured to transfer electrical changes generated by the photodiode. In one example, the oxide transistor is configured to reset the photodiode.

The stacking the gate electrode, the gate isolation layer, and the oxide layer may include: forming the gate electrode on a first isolation layer on which the transfer transistor is formed; forming the gate isolation layer on the gate electrode; forming the oxide layer on the gate isolation layer; forming a first electrode on one side of the oxide layer; and forming a second electrode on another side of the oxide layer.

The gate electrode may include doped polysilicon.

The gate isolation layer may include a silicon oxide.

The oxide layer may include an oxide-based thin film transistor (TFT) material.

The method for manufacturing an image sensing device may further include: after forming the oxide transistor, forming an interconnect structured to connect the oxide transistor and a floating diffusion region to each other.

### BRIEF DESCRIPTION OF THE DRAWINGS

FIG. 1 is a block diagram of an image sensing device based on an embodiment.

FIG. 2 shows an example structure of a unit pixel of an image sensing device based on an embodiment.

FIG. 3 shows an example structure of an oxide transistor based on an embodiment.

FIGS. 4 to 9 show an example method for manufacturing an image sensing device based on an embodiment.

### DETAILED DESCRIPTION

Features, and certain advantages in connection with specific implementations of the disclosed technology disclosed in this patent document are described by example embodiments with reference to the accompanying drawings.

The disclosed technology can be implemented in some embodiments to provide an image sensing device including a transistor that is formed using an oxide-based thin film transistor (TFT) material and a method for manufacturing the same.

The smaller the pixel size of the CMOS image sensing device, the more pixels can be disposed per unit area, which improves the image resolution, and accordingly the performance of the CMOS image sensing device can be improved.

In some implementations, image sensing pixels in an image sensing device can be highly integrated by placing pixel transistors in a stacked structure. In the case of the stacked pixel structure, however, a silicon (Si) based pixel transistor process entails a wafer bonding process during a stacking process, which can reduce process reliability and increase process costs. In addition, during the silicon (Si) based pixel transistor process, the high-temperature thermal process can deteriorate the characteristics of the image sensor. The disclosed technology can be implemented in some embodiments to address these issues by forming transistors without the wafer bonding. In this way, a high thermal process margin can be achieved, and there can be a structural advantage over the silicon (Si) based pixel transistor when manufacturing the stacked structure. The image sensing device implemented based on some embodiments can exhibit better electrical characteristics than the silicon (Si) based pixel transistor, and the degradation during the annealing process may be minimized. In some implementations, dark noise caused by a charge transfer mechanism of an oxide TFT (oxide-based TFT) may be reduced, and noise may be reduced through EHP (Electron-Hole Pair) suppression.

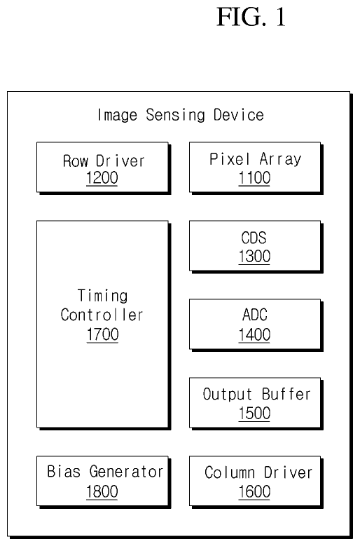

FIG. 1 is a block diagram of an image sensing device based on an embodiment.

Referring to FIG. 1, the image sensing device based on an embodiment may include a pixel array 1100, a row driver 1200, a correlated double sampler (CDS) 1300, an analog-digital converter (ADC) 1400, an output buffer 1500, a column driver 1600, a timing controller 1700, and a bias generator 1800. The components of the image sensing device illustrated are discussed by way of example only, and this patent document encompasses additions or omissions of components as necessary.

The pixel array 1100 may include a plurality of pixels arranged in a plurality of rows and a plurality of columns. In one embodiment, the plurality of pixels can be arranged in a two-dimensional pixel array including rows and columns. In another example, the plurality of unit imaging pixels can be arranged in a three-dimensional pixel array. The plurality of pixels may convert an optical signal into an electrical signal on a unit pixel basis or on a pixel group basis and the pixels in a pixel group share at least certain internal circuitry. The pixel array 1100 may receive driving signals, including a row selection signal, a pixel reset signal and a transmission signal, from the row driver 1200. Upon receiving the driving signal, corresponding pixels in the pixel array 1100 may be activated to perform operations corresponding to the row selection signal, the pixel reset signal, and the transmission signal.

The row driver 1200 may activate the pixel array 1100 to perform certain operations on the pixels in the corresponding row based on commands and control signals provided by the timing controller 1700. In one embodiment, the row driver 1200 may select at least one pixel arranged in at least one row of the pixel array 1100. The row driver 1200 may generate a row selection signal to select at least one row among the plurality of rows. The row driver 1200 may sequentially enable the pixel reset signal and the transmission signal for the pixels corresponding to the at least one selected row. Thus, a reference signal and an image signal, which are analog signals generated by each of the pixels of the selected row, may be sequentially transferred to the CDS 1300. At this time, the reference signal may be an electrical signal that is provided to the CDS 1300 when a sensing node of a pixel (e.g., floating diffusion node) is reset, and the image signal may be an electrical signal that is provided to the CDS 1300 when photocharges generated by the pixel are accumulated in the sensing node. A reference signal representing reset noise inherent in a pixel and an image signal representing intensity of incident light may be collectively referred to as a pixel signal.

CMOS image sensors may use the correlated double sampling (CDS) to remove undesired offset values of pixels known as the fixed pattern noise by sampling a pixel signal twice to remove the difference between these two samples. In some embodiments, the correlated double sampling (CDS) may remove the undesired offset value of pixels by comparing pixel output voltages obtained before and after photocharges generated by incident light are accumulated in the sensing node so that only pixel output voltages based on the incident light can be measured. In one embodiment, the CDS 1300 may sequentially sample and hold the reference signal and the image signal, which are provided to each of a plurality of column lines from the pixel array 1100. That is, the CDS 1300 may sample and hold the reference signal and the image signal which correspond to each of the columns of the pixel array 1100.

The CDS 1300 may transfer the reference signal and the image signal of each of the columns as a correlate double sampling signal to the ADC 1400 based on control signals from the timing controller 1700.

The ADC 1400 is used to convert CDS signals into digital signals for each of the columns and output the digital signal. In one embodiment, the ADC 1400 may be implemented as a ramp-compare type ADC. The ramp-compare type ADC may include a comparator circuit for comparing the analog pixel signal with a ramp signal that ramps up or down over time, and a counter that counts until the ramp signal matches the analog pixel signal. In one embodiment, the ADC 1400 may convert the correlate double sampling signal generated by the CDS 1300 for each of the columns into a digital signal, and output the digital signal.

The ADC 1400 may include a plurality of column counters corresponding to each of the columns of the pixel array 1100. Each column of the pixel array 1100 is coupled to a column counter, and image data can be generated by converting the correlate double sampling signals corresponding to each of the columns into digital signals using the column counters. In another embodiment, the ADC 1400 may include a global counter to convert the correlate double sampling signals corresponding to each of the columns into digital signals using a global code provided from the global counter.

The output buffer 1500 may temporarily hold the column-based image data provided from the ADC 1400 to output the image data. The output buffer 1500 may temporarily store the image data output from the ADC 1400 based on control signals of the timing controller 1700. The output buffer 1500 may serve as an interface to compensate for data rate differences or transmission (or processing) rate differences between the image sensing device and other devices.

The column driver 1600 may select a column of the output buffer 1500 based on a control signal from the timing controller 1700, and sequentially output the image data, which are temporarily stored in the selected column of the output buffer 1500. In one embodiment, upon receiving an address signal from the timing controller 1700, the column driver 1600 may generate a column selection signal based on the address signal and select a column of the output buffer 1500, outputting the image data as an output signal from the selected column of the output buffer 1500.

The timing controller 1700 may control at least one of the row driver 1200, the CDS 1300, the ADC 1400, the output buffer 1500, the column driver 1600, or the bias generator 1800.

The timing controller 1700 may provide a clock signal required for the operations of the respective components of the image sensing device, a control signal for timing control, and address signals for selecting a row or column, a signal that controls a level of a bias voltage applied to the pixel array 1100, and the like to at least one of the row driver 1200, the CDS 1300, the ADC 1400, the output buffer 1500, the column driver 1600, or the bias generator 1800. In an embodiment of the disclosed technology, the timing controller 1700 may include a logic control circuit, a phase lock loop (PLL) circuit, a timing control circuit, a communication interface circuit and others.

The bias generator 1800 may generate a bias voltage for suppressing a dark current generated in pixels of the pixel array 1100 and supply the generated bias voltage to the pixel array 1100.

The bias voltage may be determined during a wafer probe test of the image sensing device and stored in a one-time programmable (OTP) memory. For example, the bias voltage may be experimentally determined as a value capable of maximizing a dark current suppression effect while minimizing unnecessary power consumption without impairing performance of the image sensing device.

The bias generator 1800 may generate a voltage corresponding to the bias voltage stored in the OTP memory. In an embodiment, the OTP memory may be included in the image sensing device, and in particular, may be included in the bias generator 1800.

In an embodiment, the bias voltage may have a plurality of values. In one example, the bias voltage may have one of a plurality of values at a certain timing.

In some implementations, the plurality of values may respectively correspond to a plurality of operation modes of the image sensing device. The dark current that is generated at a low light level and the dark current that is generated at a high light level may be different from each other, and in order for the bias generator 1800 to effectively suppress the dark currents in each environment, the bias voltage may vary depending on the mode.

In some implementations, the plurality of values may respectively correspond to a plurality of areas of the pixel array 1100. Dark currents generated at different positions of the pixel in the pixel array 1100 may be different from each other, and in order for the bias generator 1800 to effectively suppress the dark current regardless of the position of the pixel, the bias voltage may vary depending on the area.

In one example, the bias voltage may be a negative voltage having a negative sign, but the disclosed technology is not limited thereto.

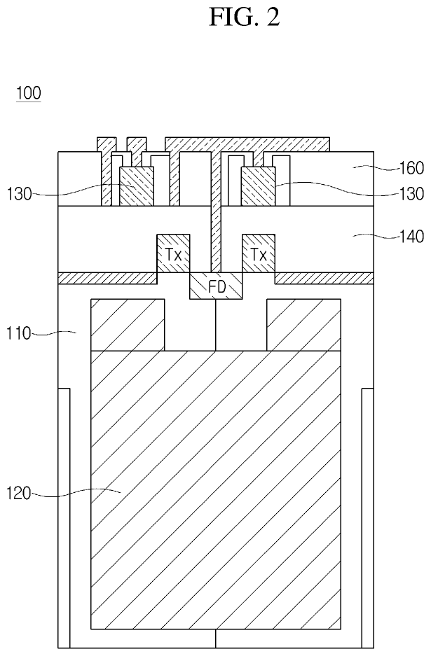

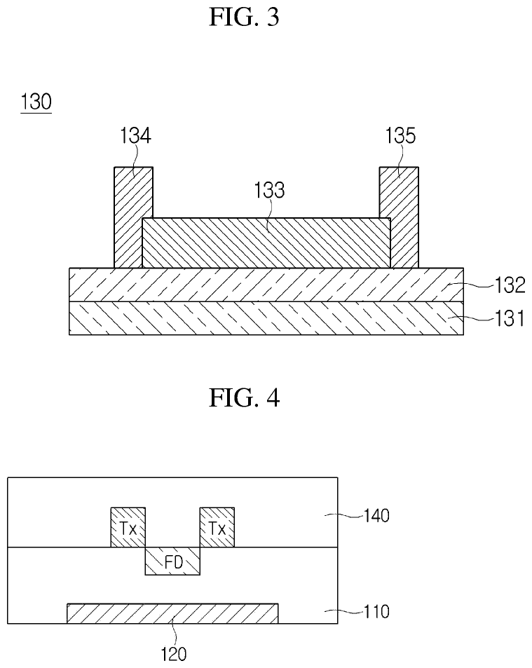

FIG. 2 shows an example structure of a unit pixel of the image sensing device based on an embodiment. FIG. 3 shows an example structure of an oxide transistor based on an embodiment.

Referring to FIG. 2, the image sensing device based on an embodiment may include a substrate 110, a photodetector 20 such as a photodiode for detects incident light to produce photocharge or electrical charge that is representative of the detected incident light, a transfer transistor Tx, a floating diffusion region FD, an oxide transistor 130, a first isolation layer 140, a second isolation layer 160. In some embodiments, the oxide transistor 130 may be an oxide thin-film transistor (oxide TFT). In one example, the oxide TFT may be a thin film transistor where the semiconductor of the thin film transistor is a metal oxide compound. In some implementations, the oxide transistor 130 may be a reset transistor that can reset the photodiode 120. In one example, the reset transistor can remove the photocharge accumulated during the previous exposure and defines the start of the subsequent exposure.

The substrate 110 may include a silicon (Si) material in a single-crystalline state in some implementations.

The photodiode 120 may be formed in an inner region of the substrate 110. An n-type impurity region and a p-type impurity region may be vertically stacked in the photodiode 120. The n-type impurity region and the p-type impurity region may be formed through an ion injection process.

The transfer transistor Tx may be formed on the substrate 110, and may transfer electrical charges (photoelectric charges or photocharge) generated in the photodiode 120 out of the photodiode 120 to the floating diffusion region FD.

The floating diffusion region FD may be formed over the photodiode 120 and below the transfer transistor Tx to hold the electrical charge that is transferred from the photodiode 120. In one example, the floating diffusion region FD is at a lower height than the transfer transistor Tx (or at a deeper depth than the transfer transistor Tx).

The floating diffusion region FD may store the photo charges, and may be formed to overlap the photodiode 120 and the transfer transistor Tx. The floating diffusion region FD may be formed to vertically overlap a central portion of the photodiode 120.

The floating diffusion region FD may be the n-type impurity region.

The oxide transistor 130 may be formed over the transfer transistor Tx. In an embodiment, the oxide transistor 130 may be one of a reset transistor, a drive transistor, or a select transistor.

Referring to FIGS. 2 and 3, in an embodiment, the oxide transistor 130 may include a gate electrode 131, a gate isolation layer 132, an oxide layer 133, a first electrode 134, and a second electrode 135.

The gate electrode 131 may be formed over the transfer transistor Tx.

In an embodiment, the gate electrode 131 may include doped polysilicon.

The gate isolation layer 132 may be formed on the gate electrode 131.

In an embodiment, the gate isolation layer 132 may include a silicon oxide.

The oxide layer 133 may be formed on the gate isolation layer 132.

In an embodiment, the oxide layer 133 may include an oxide-based thin film transistor (TFT) material such as indium gallium zinc oxide (IGZO), and zinc oxide (ZnO).

Since the oxide layer 133 can allow a transistor to be formed without wafer bonding, a subsequent thermal process may be efficiently performed, and when manufacturing a stacked structure, it has structural advantages over silicon (Si) based pixel transistors.

In addition, the oxide layer 133 including an oxide-based thin film transistor (TFT) material can exhibit superior electrical characteristics compared to silicon (Si) based pixel transistors, and can prevent or minimize deterioration that may occur during the annealing process.

In addition, noise characteristics may be improved through the oxide layer 133, which includes the oxide-based thin film transistor (TFT) material, compared to the silicon (Si) based pixel transistor.

The first electrode 134 may be formed on one side of the oxide layer 133. The first electrode 134 may include a metallic material.

The second electrode 135 may be formed on the other side of the oxide layer 133. The second electrode 135 may include a metallic material.

The first isolation layer 140 may be formed on the substrate 110. The first isolation layer 140 may include at least one of an oxide, a nitride, or an oxynitride. The transfer transistor Tx may be formed inside the first isolation layer 140.

The second isolation layer 160 may be formed on the first isolation layer 140. The second isolation layer 160 may include at least one of an oxide, a nitride, or an oxynitride. The oxide transistor 130 may be formed in the second isolation layer 160.

FIGS. 4 to 9 show an example method for manufacturing the image sensing device based on an embodiment. The method for manufacturing the image sensing device based on an embodiment may include: forming the photodiode 120 in the substrate 110; forming the photodiode 120 in the substrate; forming the transfer transistor Tx on the substrate 110; forming a photoresist layer 150 over the transfer transistor Tx; forming a channel region for forming a stacked transistor in one region of the photoresist layer 150; and forming the oxide transistor 130 in the channel region of the photoresist layer 150. The forming the oxide transistor 130 may include stacking the gate electrode 131, the gate isolation layer 132, and the oxide layer 133 in the channel region of the photoresist layer 150. The stacking the gate electrode 131, the gate isolation layer 132, and the oxide layer 133 may include: forming the gate electrode 131 on the first isolation layer 140 on which the transfer transistor Tx is formed; forming the gate isolation layer 132 on the gate electrode 131; forming the oxide layer 133 on the gate isolation layer 132; forming the first electrode 134 on one side of the oxide layer 133; and forming the second electrode 135 on the other side of the oxide layer 133. After the forming the oxide transistor 130, the method for manufacturing the image sensing device may include: forming an electrically conductive path 170 (e.g., a metal wiring) as an interconnect for connecting the oxide transistor 130 and the floating diffusion region FD to each other. In some implementations, the term “metal wiring” can be used to indicate an electrically conductive path or electrical conductor as an interconnect, which is a current-carrying line that connects devices and structures within a semiconductor device such as the image sensing device.

Referring to FIG. 4, the transfer transistor Tx may be formed on the substrate 110, after forming the photodiode 120 in the substrate 110.

After forming the transfer transistor Tx, the first isolation layer 140 may be formed through an oxide deposition process and a chemical mechanical polishing (CMP) process.

The first isolation layer 140 may include at least one of an oxide, a nitride, or an oxynitride.

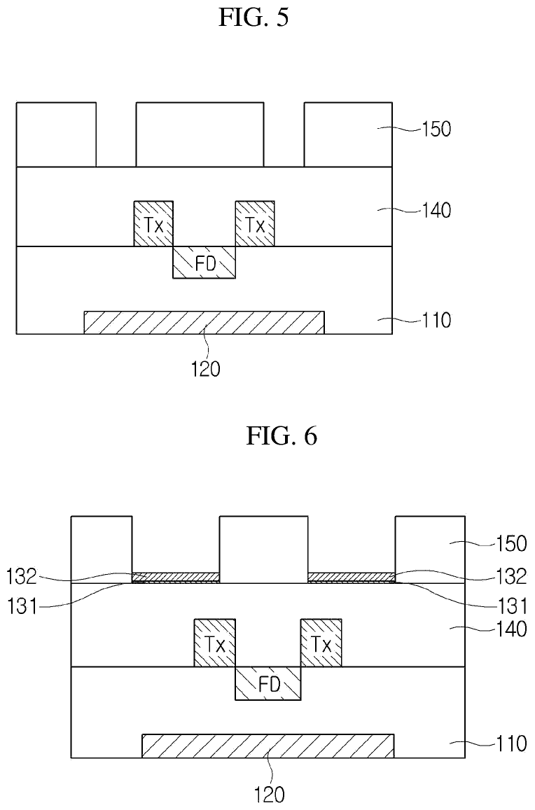

Referring to FIG. 5, the photoresist layer 150 may be formed on the first isolation layer 140. The photoresist layer 150, in which a region for the stacked transistor such as the reset transistor, the drive transistor, the select transistor, and the like is defined, may be formed using a lithography process. The channel region of the stacked transistor may be formed using the lithography process.

Referring to FIG. 6, the oxide transistor 130 may be formed on the transfer transistor Tx. The oxide transistor 130 may be formed in the channel region of the stacked transistor formed in the photoresist layer 150 on the first isolation layer 140.

In some implementations, the gate electrode 131 may be formed in the channel region of the photoresist layer 150, in which the region for the stacked transistor is located, through the deposition process, and the gate isolation layer 132 may be formed on the gate electrode 131.

The gate electrode 131 may include doped polysilicon.

The gate isolation layer 132 may include a silicon oxide.

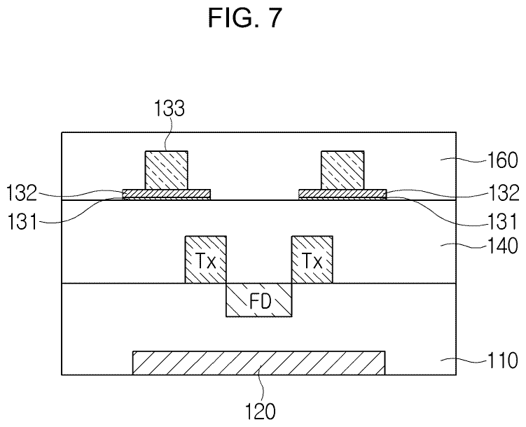

Referring to FIG. 7, the oxide layer 133 may be formed on the gate isolation layer 132 through an oxide-based thin film transistor (TFT) material deposition process and an oxide activation annealing process.

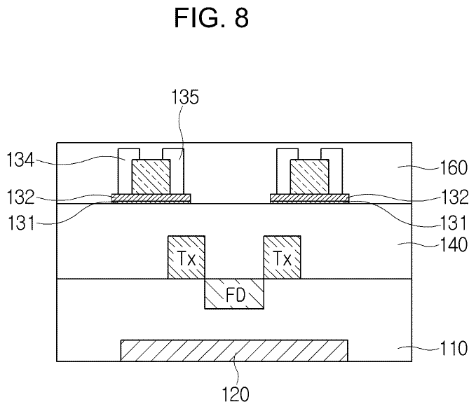

Referring to FIG. 8, the first electrode 134 and the second electrode 135 may be formed on one side and the other side of the oxide layer 133, respectively, by depositing metal capable of making ohmic contact with an oxide, such as aluminum (Al) and platinum (Pt).

In an embodiment, the first electrode 134 may be a source electrode.

In an embodiment, the second electrode 135 may be a drain electrode.

After forming the first electrode 134 and the second electrode 135, the second isolation layer 160 may be formed through an oxide deposition process and a chemical mechanical polishing (CMP) process.

The second isolation layer 160 may include at least one of an oxide, a nitride, or an oxynitride.

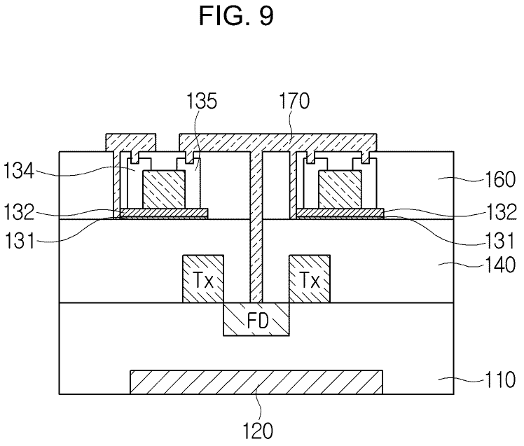

Referring to FIG. 9, after forming the oxide transistor 130, the metal wiring 170 connecting the oxide transistor 130 and the floating diffusion region FD to each other may be formed.

While this patent document contains many specifics, these should not be construed as limitations on the scope of any subject matter or of what may be claimed, but rather as descriptions of features that may be specific to particular embodiments of particular techniques. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Only a few implementations and examples of the disclosed technology are described and other implementations, enhancements and variations can be made based on what is described and illustrated in this patent document.

What is claimed is:

1. An image sensing device, comprising:
a substrate;
a photodiode formed in the substrate;
a transfer transistor formed on the substrate; and
an oxide transistor formed over the transfer transistor,
wherein the oxide transistor comprises:
a gate electrode formed over the transfer transistor;
a gate isolation layer formed on the gate electrode;
an oxide layer formed on the gate isolation layer;
a first electrode formed on one side of the oxide layer; and
a second electrode formed on another side of the oxide layer.

2. The image sensing device of claim 1, further comprising:
a floating diffusion region formed over the photodiode and below the transfer transistor.

3. The image sensing device of claim 2, further comprising:
an electrically conductive path structured to electrically connect the oxide transistor and the floating diffusion region to each other.

4. The image sensing device of claim 1,
wherein the gate electrode comprises doped polysilicon.

5. The image sensing device of claim 1,
wherein the gate isolation layer comprises a silicon oxide.

6. The image sensing device of claim 1,
wherein the oxide layer comprises an oxide-based thin film transistor (TFT) material.

7. A method for manufacturing an image sensing device, comprising:
forming a photodiode in a substrate;
forming a transfer transistor over the substrate;
forming a photoresist layer over the transfer transistor;
forming a channel region for forming a stacked transistor in one region of the photoresist layer; and
forming an oxide transistor in the channel region of the photoresist layer,
wherein the forming the oxide transistor comprises stacking a gate electrode, a gate isolation layer, and an oxide layer in the channel region of the photoresist layer.

8. The method of claim 7,
wherein the stacking the gate electrode, the gate isolation layer, and the oxide layer comprises:
forming the gate electrode on a first isolation layer on which the transfer transistor is formed;
forming the gate isolation layer on the gate electrode;
forming the oxide layer on the gate isolation layer;
forming a first electrode on one side of the oxide layer; and
forming a second electrode on another side of the oxide layer.

9. The method of claim 8,
wherein the gate electrode comprises doped polysilicon.

10. The method of claim 8,
wherein the gate isolation layer comprises a silicon oxide.

11. The method of claim 8,
wherein the oxide layer comprises an oxide-based thin film transistor (TFT) material.

12. The method of claim 8, further comprising:
after forming the oxide transistor, forming an interconnect structured to connect the oxide transistor and a floating diffusion region to each other.
